(19) United States
(12) Patent Application Publication
(10) Pub. No.: US 2025/0385674 A1
(43) Pub. Date: Dec. 18, 2025

(54) RADIATION HARDENED LOW NOISE POWER MANAGEMENT DEVICE

(71) Applicant: Raytheon Company, Arlington, VA (US)

(72) Inventors: Barry Liu, Manhattan Beach, CA (US); Randall K. Ng, Torrance, CA (US); Fernando Ayon-Serrato, Lawndale, CA (US); Richard D. Young, Lawndale, CA (US); Anup Omprakash, Los Angeles, CA (US)

(21) Appl. No.: 19/240,642

(22) Filed: Jun. 17, 2025

Related U.S. Application Data
(60) Provisional application No. 63/660,892, filed on Jun. 17, 2024.

(51) Int. Cl. H03K 19/003; H10D 89/10

(52) U.S. Cl. CPC H03K 19/00338; H03K 19/00392; H10D 89/10

(57) ABSTRACT

A power management device is provided including a circuit module configured to provide a set of voltage biases for one or more target devices. The circuit module includes a set of first transistors of a first type and disposed in a doped region, a set of well ties disposed in the doped region and located a predetermined distance from the set of first transistors, a set of second transistors of a second type and disposed outside the doped region, and a set of substrate ties disposed between the doped region and the set of second transistors.

### CROSS-REFERENCE TO RELATED APPLICATIONS

This application claims the benefit of U.S. Provisional Application 63/660,892 filed Jun. 17, 2024, the disclosure of which is incorporated herein by reference in its entirety.

### GOVERNMENT LICENSE RIGHTS

This invention was made with Government support under contract HQ0856-21-C-0003 PO: 1022000209. The Government has certain rights in the invention.

### BACKGROUND

The present disclosure relates to a power management device and, in particular, to a low noise power management device which is hardened against radiation environments.

### SUMMARY

Disclosed are a low noise power management device hardened against radiation environments. More particularly, the present disclosure provides for low noise power management devices, assemblies, and circuit layouts supportive of the same.

Example embodiments of the present disclosure are directed to a power management device including: a circuit module configured to provide a set of voltage biases for one or more target devices, wherein the circuit module includes: a set of first transistors of a first type and disposed in a doped region; a set of well ties disposed in the doped region and located a predetermined distance from the set of first transistors; a set of second transistors of a second type and disposed outside the doped region; and a set of substrate ties disposed between the doped region and the set of second transistors.

In any one or combination of the embodiments disclosed herein, the set of first transistors include p-channel field-effect transistors (PFETs); the set of second transistors include n-channel field-effect transistors (NFETs); and the doped region includes an N-well.

In any one or combination of the embodiments disclosed herein, the set of well ties are arranged in a first direction and extend further than the set of first transistors in the first direction.

In any one or combination of the embodiments disclosed herein, the set of substrate ties are arranged in a first direction, extend further than the set of first transistors in the first direction, and completely extend further than the set of second transistors in the first direction.

In any one or combination of the embodiments disclosed herein, the power management device further includes: configuration circuitry configured to provide, to the circuit module, configuration signals for setting respective parameters associated with providing the set of voltage biases, wherein the configuration circuitry includes triple mode redundant flip-flops.

In any one or combination of the embodiments disclosed herein, the configuration circuitry includes: a set of configuration circuits; and refresh rate control circuitry; each configuration circuit of the set of configuration circuits includes: a triple mode redundant flip-flop; and voter circuitry coupled to respective outputs of the triple mode redundant flip-flop; and the refresh rate control circuitry is configured to: calculate, based on a target radiation environment and a target voltage bias of the set of voltage biases, a refresh rate associated with refreshing the triple mode redundant flip-flop for a configuration circuit of the set of configuration circuits; and provide a clock signal to the triple mode redundant flip-flop according to the refresh rate.

In any one or combination of the embodiments disclosed herein, the set of voltage biases satisfy a target noise performance threshold associated with the one or more target devices and a target environment.

In any one or combination of the embodiments disclosed herein, the power management device further includes: voltage sensing circuitry configured to provide a first feedback signal to the circuit module based on one or more voltages sensed by the voltage sensing circuitry; and current sensing circuitry configured to provide a second feedback signal to the circuit module based on one or more currents sensed by the current sensing circuitry, wherein the circuit module is configured to modify or maintain one or more voltage biases of the set of voltage biases based on one or more of the first feedback signal and the second feedback signal.

Example embodiments of the present disclosure are directed to a system including: a printed wiring board; one or more target devices coupled to the printed wiring board; and a power management device coupled to the printed wiring board and including a circuit module, wherein the circuit module is configured to provide a set of voltage biases for the one or more target devices and includes: a set of first transistors of a first type and disposed in a doped region; a set of well ties disposed in the doped region and located a predetermined distance from the set of first transistors; a set of second transistors of a second type and disposed outside the doped region; and a set of substrate ties disposed between the doped region and the set of second transistors.

In any one or combination of the embodiments disclosed herein: the set of first transistors include p-channel field-effect transistors (PFETs); the set of second transistors include n-channel field-effect transistors (NFETs); and the doped region includes an N-well.

In any one or combination of the embodiments disclosed herein, the set of well ties are arranged in a first direction and extend further than the set of first transistors in the first direction.

In any one or combination of the embodiments disclosed herein, the set of substrate ties are arranged in a first direction, extend further than the set of first transistors in the first direction, and completely extend further than the set of second transistors in the first direction.

In any one or combination of the embodiments disclosed herein, the power management device further includes: configuration circuitry configured to provide, to the circuit module, configuration signals for setting respective parameters associated with providing the set of voltage biases, wherein the configuration circuitry includes triple mode redundant flip-flops.

In any one or combination of the embodiments disclosed herein: the configuration circuitry includes: a set of configuration circuits; and refresh rate control circuitry; each configuration circuit of the set of configuration circuits includes: a triple mode redundant flip-flop; and voter circuitry coupled to respective outputs of the triple mode redundant flip-flop; and the refresh rate control circuitry is configured to: calculate, based on a target radiation environment and a target voltage bias of the set of voltage biases, a refresh rate associated with refreshing the triple mode redundant flip-flop for a configuration circuit of the set of configuration circuits; and provide a clock signal to the triple mode redundant flip-flop according to the refresh rate.

In any one or combination of the embodiments disclosed herein, the set of voltage biases satisfy a target noise performance threshold associated with the one or more target devices and a target environment.

In any one or combination of the embodiments disclosed herein, the power management device further includes: voltage sensing circuitry configured to provide a first feedback signal to the circuit module based on one or more voltages sensed by the voltage sensing circuitry; and current sensing circuitry configured to provide a second feedback signal to the circuit module based on one or more currents sensed by the current sensing circuitry, wherein the circuit module is configured to modify or maintain one or more voltage biases of the set of voltage biases based on one or more of the first feedback signal and the second feedback signal.

Additional features and advantages are realized through the techniques of the present disclosure. Other embodiments and aspects of the disclosure are described in detail herein and are considered a part of the claimed technical concept. For a better understanding of the disclosure with the advantages and the features, refer to the description and to the drawings.

### BRIEF DESCRIPTION OF THE SEVERAL VIEWS OF THE DRAWINGS

For a more complete understanding of this disclosure, reference is now made to the following brief description, taken in connection with the accompanying drawings and detailed description, wherein like reference numerals represent like parts.

FIG. 1A and FIG. 1B illustrate examples of a system in accordance with one or more embodiments of the present disclosure.

FIG. 2 illustrates a plan view of an example layout implementation of the circuit module of a power management device in accordance with one or more embodiments of the present disclosure.

FIG. 3 illustrates an example of configuration circuitry of the power management device in accordance with one or more embodiments of the present disclosure.

FIG. 4 illustrates a printed wiring board which may provide the control of 12 biases according to some other approaches.

### DETAILED DESCRIPTION

A detailed description of one or more embodiments of the disclosed apparatus and method are presented herein by way of exemplification and not limitation with reference to the Figures.

Electronic hardware for some space and guidance applications may be limited based on device size and mass. For many system designs, multiple biases may be required for devices such as, for example, application specific integrated circuits (ASICs), field programmable gate arrays (FPGAs), and focal plane arrays (FPAs). The physical implementation of the radiation hardened low noise power management device resulted in 21 output voltage biases which lends itself to a variety of applications. For EO/IR missions, this could bias up to three separate focal plane arrays; for digital FPGAs or ASICs, it could supply all the biases required. Historically, in some approaches, the biases are accomplished with complex analog circuitry satisfying very low noise specifications, as noise may impact FPA performance (e.g., signal-to-noise ratio (SNR)).

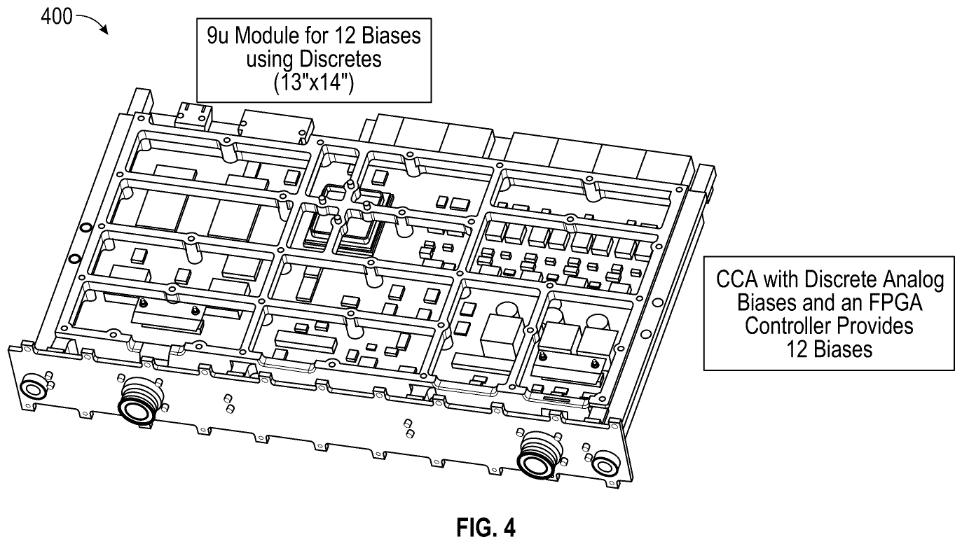

In a comparative example, some other approaches use a rather large printed wiring board (PWB) which may provide the control of 12 biases on a large, 9u (13″×14″) sized PWB (later illustrated at FIG. 4).

Embodiments of the present disclosure include providing a radiation hardened low noise power management device that embeds an FPGA based state machine function in a single monolithic die, in which the radiation hardened low noise power management device is capable of generating programmable, low noise biases without all the additional discrete devices implemented in other approaches.

The radiation hardened low noise power management device described herein may be referred to as a radiation hardened low noise power management integrated circuit ASIC (RH_LNPMIC ASIC), a radiation hardened low noise power management integrated circuit (RH_LNPMIC), a radiation hardened low noise power management device (RH_LNPMD), a radiation hardened low noise power management ASIC, a power management integrated circuit (PMIC), and the like.

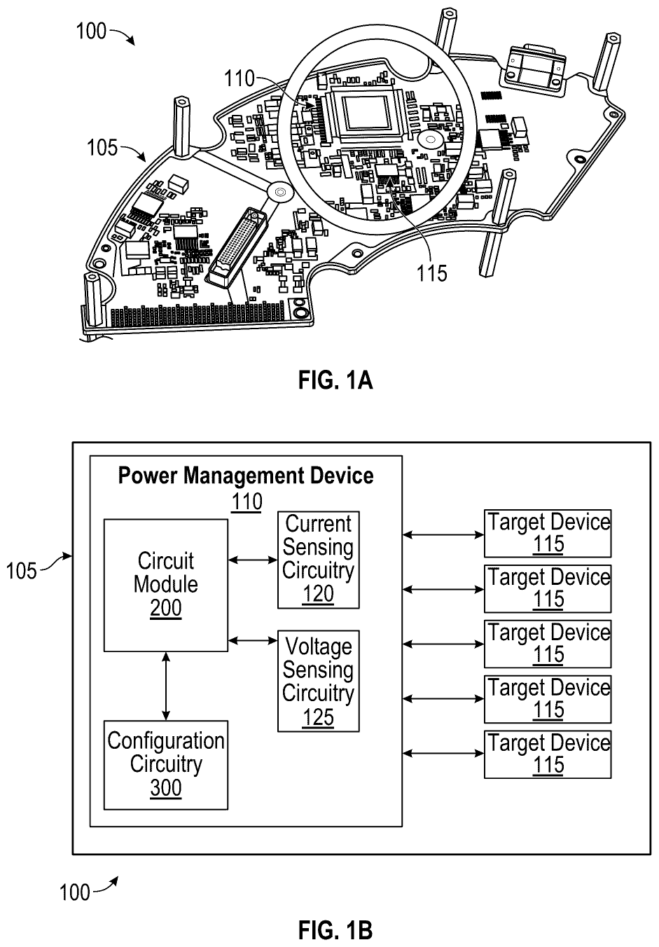

The mass savings provided by the embodiments described herein is significant. The equivalent comparative example would require QTY. 3 9u slices, totaling about 11 pounds, to provide an equivalent number of biases and control. In contrast, embodiments of the present disclosure provide a radiation hardened low noise power management device on a PWB 105 (e.g., 6u PWB as illustrated in the example of FIG. 1A), in which the combined product is about 2 pounds and approximately 6″×4″, but provides 21 biases.

The ASIC is Spacewire programmable via an internal state machine for parameters such as, output voltage, ramp rate, over current protection, over and under voltage protection, and output current (up to 0.8 A). The device is scalable and can be connected to one another via their Spacewire interfaces to allow for startup and shutdown power sequencing. The device provides multiple methods of loading all the programmable bits, such as, for example, via direct interface to non-volatile memory source, via scan chain, and via Spacewire interface through the PMIC device.

Embodiments of the present disclosure support implementing the radiation hardened low noise power management device described herein for other complex devices, such as modern FPGAs or ASICs.

Embodiments of the present disclosure provide a power management device suitable for any design application that requires a relatively large number of voltages that drive components included in a PWB area. Embodiments of the present disclosure support incorporating the radiation hardened low noise power management device into an SOC w/appropriate Technology Node.

Embodiments of the present disclosure support implementing the radiation hardened low noise power management device described herein as an integrated circuit device such as, for example, an analog ASIC device

FIG. 1A and FIG. 1B illustrate examples of a system 100 in accordance with one or more embodiments of the present disclosure. The system 100 includes a PWB 105 and a power management device 110 (i.e., a radiation hardened low noise power management device described herein). The system 100 includes a target device 115. In some embodiments, the target device 115 may be included on (coupled to the PWB 105). For example, the power management device 110 and the target device 115 may be electrically coupled to each other via the connectors included in the PWB 105.

In some embodiments, (not illustrated), the target device 115 may be on another PWB 105 different from the PWB 105, and the target device 115 may be coupled to the power management device 110 via connectors which span between the PWB 105 and the other PWB 105. In some embodiments, the system 100 may include multiple target devices 115, and the power management device 110 may provide voltage biases to each of the multiple target devices 115.

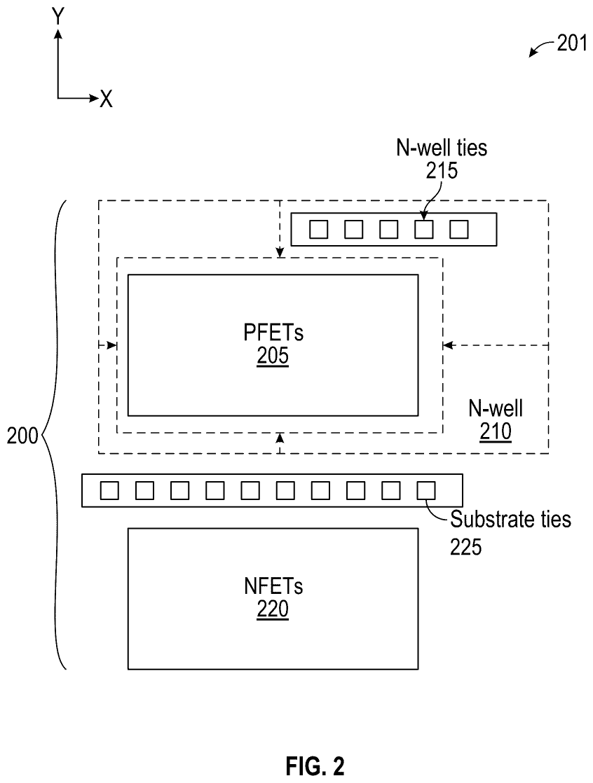

The power management device 110 may include a circuit module 200 configured to provide voltage biases for each of the target devices 115. Example aspects of the circuit module 200 are later described herein with reference to FIG. 2.

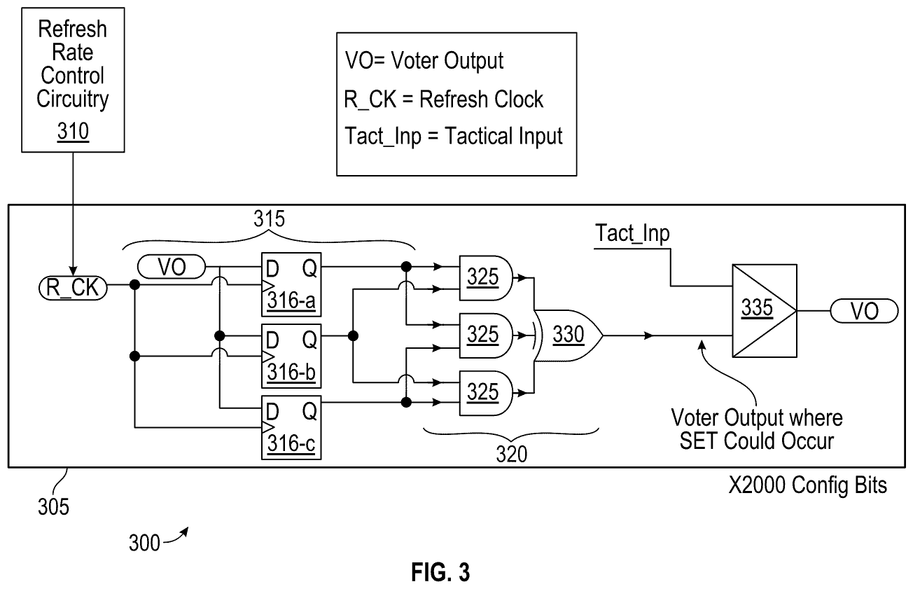

The power management device 110 may include configuration circuitry 300 configured to provide, to the circuit module 200, configuration signals for setting respective parameters associated with providing the voltage biases. Example aspects of the configuration circuitry 300 are later described herein with reference to FIG. 3.

According to one or more embodiments of the present disclosure, the power management device 110 may serve as a fundamental building block for any mission since the power management device 110 may provide the biases for operating circuitry associated with the mission (e.g., providing biases for establishing proper operating conditions for the component). Generalizing, embodiments of the present disclosure provide a power management device 110 for applications for which multiple voltages are to be provided within a small PWB footprint. For example, for some target devices 115 (e.g., FPGAs, RF devices, ASICs, and the like) which need 6 or more voltage biases with tight tolerances, the power management device 110 is capable of consolidating most of the low-dropout (LDO) voltage regulators into a monolithic, but with reduced PWB area and reduced parts costs compared to other approaches.

The power management device 110 may support implementations in electro-optic infrared (EO/IR) systems, but is not limited thereto. In some examples, the power management device 110 may be implemented for applications related to generic space flight programs.

In some aspects, the noise performance provided by the power management device 110 satisfies noise performance thresholds for these programs. That is, the power management device 110 may provide voltage biases which satisfy target noise performance thresholds (e.g., low noise) with respect to the target devices 115 and an environment in which the target devices 115 are to be implemented.

As the power management device 110 described herein is implemented as an integrated circuit (e.g., an ASIC) versus a discrete design including separate hardware components, the power management device 110 provides both power and mass savings. In some embodiments, the mass savings is approximately a factor of 5 for the amount of biases the power management device 110 can provide.

In some aspects, the power management device 110 can power SOC type FPGAs (i.e., target devices 115) that have multiple voltages, thereby reducing the number of discrete devices for powering the SOC type FPGAs compared to other approaches. The power management device 110 may provide the same functionality (and in some aspects, an increased amount of functionality and functions) compared to approaches which implement multiple, large cards in one card, and accordingly, for example, the power management device 110 provides savings with respect to mass, cost, and power.

In some aspects, the power management device 110 (RH_LNPMD ASIC) is radiation hardened with extensive radiation data for all natural environments The power management device 110 includes structures providing mitigation features which make the design of the power management device 110 robust to radiation effects. Example aspects of the mitigation features provided by the power management device 110 are described herein.

According to one or more embodiments of the present disclosure, the power management device 110 is capable of biasing electronic devices (i.e., target devices 115) including, but not limited to, FPGAs. Accordingly, for example, the power management device 110 is applicable to digital designs including electronics, in that the digital design implementations may remain available and have increased reliability in radiation environments, as the power management device 110 is able to bias the electronics in such radiation environments. Aspects of the power management device 110 provide a substantial reduction in PWB size (e.g., compared to the PWB in the comparative example of FIG. 4) and material costs compared to other approaches which are tied to using other vendor discrete solutions.

In some aspects, the power management device 110 may be a multipurpose ASIC device (a multipurpose radiation hardened low noise power management IC ASIC), and the power management device 110 is not limited to power management and providing bias voltages as described herein.

According to one or more embodiments of the present disclosure, the power management device 110 is capable of effectively functioning (working) in any radiation environment (e.g., any natural radiation environment). For example, the power management device 110 may be implemented in association with a LEO, MEO, or GEO mission. The baseline ASIC technology node is a trusted node for programs implemented on-shore AND trust.

In some aspects, the power management device 110 uses 3 active control topologies such that any of the programmable bits are spared in a redundant path. Any single bit upset due to heavy ions, protons or neutrons, will be identified and the error isolated and actively corrected. Example aspects of the control topologies are later described with reference to FIG. 3.

Aspects of the power management device 110 support quick startup via a non-volatile memory. In some aspects, the power management device 110 supports configuration/programmability via a spacecraft communication network (e.g., Spacewire interface). Aspects of the power management device 110 support implementing a firmware update for configuring the power management device 110 for parameter updates such as, for example, new startup/shutdown sequences, new bias levels or new loads. In contrast, other approaches may be reliant on design modifications (e.g., hardware design modifications, component modifications or component replacement, or the like) each time for new startup/shutdown sequences, new biases, or new loads.

Embodiments of the present disclosure include implementing strategic guard rails (e.g., substrate ties to ground) around sensitive regions in the circuit layout of the power management device 110 in association with reducing the probability of bit upsets. Example aspects of the guard rails are later described with reference to FIG. 2.

Aspects of the power management device 110 support a reduction in mass and material substantially compared to bias designs in some other approaches. Accordingly, for example, a product (e.g., a payload, a satellite, space probe, or spacecraft, or other guided vehicle or apparatus) including the power management device 110 may be implemented such that an increased number of functions and associated components (e.g., hardware circuitry, ICs, discrete components, and the like) may reside in the product. In an example, a single power management device 110 supported by aspects of the present disclosure is capable of providing the same (or an increased amount) of functionality as and can replace three 6u PWBs (e.g., three of the PWB later described with reference to FIG. 4), in addition to reducing material costs by 3 orders of magnitude.

The power management device 110 is scalable for different electronic architectures. For example, the power management device 110 may include programmable outputs for FPAs and may be implemented for arrays that are 8 k×8 k or larger. In some aspects, the power management device 110 may include biases for SOC type devices that have multiple low current or reference biases with tight voltage requirements.

The power management device 110 provides features for powering FPGAs. In an example, the power management device 110 is capable of powering and providing biases for an adaptive compute acceleration platform (ACAP). For example, the power management device 110 is capable of powering and providing biases for ASICS, FPGAs, memories, ADCs, DACs, and SOC devices. Aspects of the power management device 110 provide a size and cost advantage for designs (e.g., payloads, PWBs, and the like) utilizing the power management device 110. For example, the material and PWB size savings can be utilized on any usage of ASICS, FPGAS, memories, ADCs, DACs, and SOC devices.

According to one or more embodiments of the present disclosure, the power management device 110 is a single piece part providing which may be implemented with less complex infrastructure, analysis, and manufacturing.

Embodiments of the power management device 110 described herein provide various improvements over other approaches. For example, space devices are a subset of all electronics and may not have the wider breadth of devices used in airborne designs. The customary power subsystem designs for space devices result in using radiation tested LDOs or switchers.

The power management device 110 described herein has multiple purposes with programmable voltages and programmable output currents with OCP, OVP, UVP and feedback to adjust the voltages and current. No single part, commercial or otherwise, has these features.

In some embodiments, the power management device 110 can be implemented with a negative bias ASIC with the same type of programmability as described herein.

In some embodiments, for high current outputs that exceed the technology associated with some components (e.g., FETS) of the power management device 110, the power management device 110 can control external FETs and still provide the current and voltage feedback to ensure outputs are stable over time.

The power management device 110 provides a single ASIC cost (RE) compared to the higher number of costs all the hi-reliability a discrete design would involve. For example, costs associated with a comparative discrete design may include radiation lot acceptance (RLAT) fees, part issues such as obsolescence, GIDEP alerts, and the logistics of having to order many different devices versus a single ASIC. The power management device 110 provides significant mass, material, and volume savings compared to the discrete design. The power management device 110 can replace an entire unit to a single slice.

A comparison to other solutions is described herein. According to one or more embodiments of the present disclosure, the power management device 110 is a digital ASIC for digital focal plane arrays and affords low noise voltage biases. The power management device 110 contains feedback via voltage and current sensing circuitry to correct and maintain the biases. The design of the power management device 110 is designed to be compatible with existing digital read out ICs (ROICs).

For example, the power management device 110 may include voltage sensing circuitry 120 configured to provide a first feedback signal to the circuit module 200 based on one or more voltages sensed by the voltage sensing circuitry 120. In an example, the voltage sensing circuitry 120 may sense or measure voltages associated with a voltage bias being provided to a target device 115.

The power management device 110 may include current sensing circuitry 125 configured to provide a second feedback signal to the circuit module based on one or more currents sensed by the current sensing circuitry 125. In an example, the current sensing circuitry 125 may sense or measure currents associated with a voltage bias being provided to a target device 115.

The circuit module 200 may modify or maintain one or more voltage biases to be provided to a target device 115 based on the first feedback signal, the second feedback signal, or both. Though the sensing circuitry (e.g., voltage sensing circuitry 120, current sensing circuitry 125) is described as being included in the power management device 110, embodiments of the present disclosure are not limited thereto. In some additional and/or alternative embodiments, the sensing circuitry (e.g., voltage sensing circuitry 120, current sensing circuitry 125) may be separate from the power management device 110.

The power management device 110 is capable of being used for IR or visible FPAs. Other solutions at most provide ASIC solutions for analog focal planes. The solutions fail to provide a digital ASIC for digital focal planes as described herein.

Aspects of the power management device 110 described herein may be implemented for EOIR missions which require a large number of biases and are constrained with respect to mass, power and volume. Aspects of the power management device 110 described herein may be implemented for FPGA designs which are constrained for PWB area and are to implement multiple biases for a target device 115.

In some applications, embodiments of the power management device 110 provide a PWB area which is reduced by about 33% compared to PWB implementations absent the power management device 110.

Aspects of the power management device 110 described herein may support any low noise application. For example, the power management device 110 provides features for and is capable of biasing low noise applications (e.g., commercial low noise applications).

Aspects of the power management device 110 described herein support reduced costs. The example design implementations described herein of the power management device 110 support a robust low cost fabrication and assembly approach implementing flight approved materials and processes to reduce program costs when comparing to the discrete solution which requires an FPGA and relatively large number of active analog devices. Compared to the discrete solution, use of the power management device 110 may save a large amount (e.g., $200K for the power management device 110 versus $3M for the discrete solution) of material costs for space and a sizeable amount of labor.

Advanced technologies require many biases that take up valuable real estate. Aspects of the power management device 110 described herein provide benefits in material costs, space, and complexity for any applications that use these advanced technologies.

Aspects of the power management device 110 described herein support is a robust low cost technology insertion which may be implemented in various flight programs (e.g., space programs, missiles, and the like).

FIG. 2 illustrates a plan view of an example layout implementation 201 of the circuit module 200, supportive of implementing a radiation hardened low noise power management device (e.g., power management device 110 described herein) in accordance with one or more embodiments of the present disclosure.

The layout implementation 201 may include the addition of substrate ties 225, the addition of N-well ties 215, and a reduction of the area of the N-well 210. The layout implementation 201 includes implementing guard rings (or partial guard rings) for the p-channel field effect transistors (PFETs) 205 using the N-well ties 215. Aspects of the layout implementation 201 described herein support increased robustness to all radiation environments (e.g., natural environments). For example, aspects of the present disclosure support setting or modifying quantities, sizes, configurations, spacing or locations, and the like of the PFETs 205, n-channel field effect transistors (NFETs) 220, N-well ties 215, substrate ties 225, N-wells 210, and the like in a manner which provides increased robustness to all radiation environments (e.g., natural environments) as described herein.

Aspects of the layout implementation 201 reduce the susceptibility of digital logic to prevent the outputs from going to incorrect output voltages. Prompt dose mitigation techniques provided by the layout implementation 201 include adding N-well ties 215 uniformly to ensure that Vdd is maintained throughout the chip (i.e., the power management device 110). Similarly, the substrate potential needed to maintain ground potential uniformly was achieved through the use of substrate ties 225 across the chip. Both of these techniques help funnel excess electrons and holes created by the prompt dose environment away from sensitive nodes, which could disrupt ASIC operation. For example, for an ASIC implementation of the power management device 110, the voltage regulators in the ASIC may have guard rings surrounding them in the layout to help conduct additional noise and charges away from Vdd to prevent erroneous levels from being generated.

Example impacts of the substrate ties 225 and N-well ties 215 of the layout implementation 201 are described herein. The substrate ties 225 and N-well ties 215 reduce the substrate and N-well resistances between and around NFETs 220 and PFETs 205. This effectively makes circuits highly resistant to latch-up mechanisms since the lower resistance makes it harder to turn on the parasitic P-N-P-N structure.

The substrate ties 225 and N-well ties 215 may make the local potential “stiffer.” Radiation events can create excess charge, which will want to go to either ground or VDD potential depending on its polarity. Without a short path to ground or VDD, these charges can induce local potentials that can either bring the local ground up or the local VDD down. This can result in bit upsets or transients that can cause malfunctions in the circuit. Adding the substrate ties 225 and N-well ties 215 described herein significantly reduces the impact of the excess charge, changing the local potential.

Example impacts of the reduction of the area of the N-well 210 in the layout implementation 201 are described herein. The majority of charge collection may occur where a P-N junction exists. In general, one of the sources of large area P-N junctions is around PFETs, which have a large N-well that sits on top of the P-type substrate. During a radiation event, these areas can collect significant amounts of excess charge that can negatively impact operation of circuits in a radiation environment. According to one or more embodiments of the present disclosure, the area of the N-well 210 is reduced such that the size of the area of the N-well 210 minimizes charge collection and enables uninterrupted operation during radiation events.

Accordingly, with reference to the example of the circuit module 200 in FIG. 2, the circuit module 200 may include a set of first transistors (e.g., PFETs 205) of a first type and disposed in a doped region (e.g., N-well 210), a set of well ties (e.g., N-well ties 215) disposed in the doped region and located a predetermined distance from the set of first transistors, a set of second transistors (e.g., NFETs 220) of a second type and disposed outside the doped region, and a set of substrate ties 225 disposed between the doped region and the set of second transistors. The set of well ties (e.g., n-well ties 215) may be arranged in a first direction (e.g., X-direction) and extend further than the set of first transistors in the first direction. Further, for example, the set of substrate ties 225 may be arranged in the first direction, extend further than the set of first transistors in the first direction, and extend further than the set of second transistors in the first direction.

FIG. 3 illustrates an example of the configuration circuitry 300 of the power management device 110 in accordance with one or more embodiments of the present disclosure.

The configuration circuitry 300 may include configuration circuits 305 and refresh rate control circuitry 310. Each of the configuration circuits 305 may provide a configurable bit (also referred to herein as a programmable digital bit). In an example, the configuration circuitry 300 (respectively by way of the configuration circuits 305) may provide about 2000 configurable bits. For simplicity, a single configuration circuit 305 associated with providing a respective configurable bit is illustrated.

In some aspects, each configuration circuit 305 may include a triple mode redundant flip-flop (TMR-FF) 315 and voter circuitry 320 coupled to respective outputs of the triple mode redundant flip-flop 315. The triple mode redundant flip-flop 315 may include flip-flops 316 (e.g., flip-flop 316-a through flip-flop 316-c).

In the example of FIG. 3, the voter circuitry 320 is implemented using a combination of AND gates 325 and an XOR gate 330. However, it is to be understood that the voter circuitry 320 is not limited to the example logic gates for implementing functions of the voter circuitry 320.

Compared to some other flip-flops which may be more vulnerable to particle strikes in a radiation environment, the implementation of the triple mode redundant flip-flop 315 has a triple modular redundancy which provides radiation-hardening which is robust against such particle strikes.

In some embodiments, through the implementation of the refresh rate control circuitry 310, the triple mode redundant flip-flop 315, and the voter circuitry 320, the power management device 110 may prevent single event upsets from upsetting any of the programmable digital bits.

An example is described for the case in which there are about 2000 configurable bits for settings (e.g., output voltage, over voltage setting, under voltage setting, over current, startup/shutdown sequence, and the like) with respect to voltage biases to be provided to a target device 115. In some cases, for example, if a single bit upsets in a flip-flop 316-a of the triple mode redundant flip-flop 315, the other two flip-flops 316 (e.g., flip-flop 316-b, flip-flop 316-c) of the redundant flip-flop 315 will correct the flip-flop 316-a based on a programmable clock rate. Embodiments of the present disclosure include providing the configuration of the configuration circuit 305 (and included components) illustrated at FIG. 3 for each of the configurable bits.

An inherent issue with a TMR-FF is the vulnerability of the TMR-FF to the voter at the output of the TMR-FFs. Embodiments of the present disclosure include using logic circuitry (e.g., refresh rate control circuitry 310) to refresh a programmable refresh period.

For example, with reference to FIG. 3, the refresh rate control circuitry 310 may be configured to calculate, based on a target radiation environment and a target voltage bias (or target voltage biases) to be provided to a target device 115, a refresh rate associated with refreshing the triple mode redundant flip-flop 315 for the configuration circuit 305. In an example, the refresh rate control circuitry 310 may provide a clock signal R_CK (‘refresh clock’) to the triple mode redundant flip-flop 315 according to the refresh rate.

Accordingly, for example, using the refresh rate control circuitry 310 may overcome problems associated with refreshing too quickly, as refreshing too quickly may increase the probability of latching a single event transient (SET) at the voter output VO of the configuration circuit 305, defeating the triple mode redundancy.

In an example, embodiments of the present disclosure include calculating the refresh rate based on each program's radiation environment. By providing the refresh rate as a programmed value, the power management device 110 has inherent flexibility to all orbits. In an example implementation with respect to GEO, embodiments of the present disclosure include refreshing once per hour.

The configuration circuit 305 may further include a block 335 which receives a tactical input Tact_Inp and the voter output VO (from the voter circuitry 320) where SET may occur.

FIG. 4 illustrates a 9u sized PWB 400 which may provide the control of 12 biases according to some other approaches. In the comparative example of FIG. 4, separate discrete hardware components are implemented instead of the power management device 110 supported by aspects of the present disclosure.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

The corresponding structures, materials, acts and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the technical concepts in the form disclosed. Many modifications and variations will be apparent to those of ordinary skill in the art without departing from the scope and spirit of the disclosure. The embodiments were chosen and described in order to best explain the principles of the disclosure and the practical application and to enable others of ordinary skill in the art to understand the disclosure for various embodiments with various modifications as are suited to the particular use contemplated.

What is claimed is:

1. A power management device comprising:
a circuit module configured to provide a set of voltage biases for one or more target devices, wherein the circuit module comprises:
a set of first transistors of a first type and disposed in a doped region;
a set of well ties disposed in the doped region and located a predetermined distance from the set of first transistors;
a set of second transistors of a second type and disposed outside the doped region; and
a set of substrate ties disposed between the doped region and the set of second transistors.

2. The power management device of claim 1, wherein:
the set of first transistors comprise p-channel field-effect transistors (PFETs);
the set of second transistors comprise n-channel field-effect transistors (NFETs); and
the doped region comprises an N-well.

3. The power management device of claim 1, wherein the set of well ties are arranged in a first direction and extend further than the set of first transistors in the first direction.

4. The power management device of claim 1, wherein the set of substrate ties are arranged in a first direction, extend further than the set of first transistors in the first direction, and completely extend further than the set of second transistors in the first direction.

5. The power management device of claim 1, further comprising:
configuration circuitry configured to provide, to the circuit module, configuration signals for setting respective parameters associated with providing the set of voltage biases,
wherein the configuration circuitry comprises triple mode redundant flip-flops.

6. The power management device of claim 5, wherein:
the configuration circuitry comprises:
a set of configuration circuits; and
refresh rate control circuitry;
each configuration circuit of the set of configuration circuits comprises:
a triple mode redundant flip-flop; and
voter circuitry coupled to respective outputs of the triple mode redundant flip-flop; and
the refresh rate control circuitry is configured to:
calculate, based on a target radiation environment and a target voltage bias of the set of voltage biases, a refresh rate associated with refreshing the triple mode redundant flip-flop for a configuration circuit of the set of configuration circuits; and
provide a clock signal to the triple mode redundant flip-flop according to the refresh rate.

7. The power management device of claim 1, wherein the set of voltage biases satisfy a target noise performance threshold associated with the one or more target devices and a target environment.

8. The power management device of claim 1, further comprising:
voltage sensing circuitry configured to provide a first feedback signal to the circuit module based on one or more voltages sensed by the voltage sensing circuitry; and
current sensing circuitry configured to provide a second feedback signal to the circuit module based on one or more currents sensed by the current sensing circuitry,
wherein the circuit module is configured to modify or maintain one or more voltage biases of the set of voltage biases based on one or more of the first feedback signal and the second feedback signal.

9. A system comprising:
a printed wiring board;
one or more target devices coupled to the printed wiring board; and
a power management device coupled to the printed wiring board and comprising a circuit module,
wherein the circuit module is configured to provide a set of voltage biases for the one or more target devices and comprises:
a set of first transistors of a first type and disposed in a doped region;
a set of well ties disposed in the doped region and located a predetermined distance from the set of first transistors;
a set of second transistors of a second type and disposed outside the doped region; and
a set of substrate ties disposed between the doped region and the set of second transistors.

10. The system of claim 9, wherein:
the set of first transistors comprise p-channel field-effect transistors (PFETs);
the set of second transistors comprise n-channel field-effect transistors (NFETs); and
the doped region comprises an N-well.

11. The system of claim 9, wherein the set of well ties are arranged in a first direction and extend further than the set of first transistors in the first direction.

12. The system of claim 9, wherein the set of substrate ties are arranged in a first direction, extend further than the set of first transistors in the first direction, and completely extend further than the set of second transistors in the first direction.

13. The system of claim 9, wherein the power management device further comprises:
configuration circuitry configured to provide, to the circuit module, configuration signals for setting respective parameters associated with providing the set of voltage biases,
wherein the configuration circuitry comprises triple mode redundant flip-flops.

14. The system of claim 13, wherein:
the configuration circuitry comprises:
a set of configuration circuits; and
refresh rate control circuitry;
each configuration circuit of the set of configuration circuits comprises:
a triple mode redundant flip-flop; and
voter circuitry coupled to respective outputs of the triple mode redundant flip-flop; and
the refresh rate control circuitry is configured to:
calculate, based on a target radiation environment and a target voltage bias of the set of voltage biases, a refresh rate associated with refreshing the triple mode redundant flip-flop for a configuration circuit of the set of configuration circuits; and
provide a clock signal to the triple mode redundant flip-flop according to the refresh rate.

15. The system of claim 9, wherein the set of voltage biases satisfy a target noise performance threshold associated with the one or more target devices and a target environment.

16. The system of claim 9, wherein the power management device further comprises:
voltage sensing circuitry configured to provide a first feedback signal to the circuit module based on one or more voltages sensed by the voltage sensing circuitry; and
current sensing circuitry configured to provide a second feedback signal to the circuit module based on one or more currents sensed by the current sensing circuitry,
wherein the circuit module is configured to modify or maintain one or more voltage biases of the set of voltage biases based on one or more of the first feedback signal and the second feedback signal.
